(19) United States
(12) Patent Application Publication
(10) Pub. No.: US 2010/0093128 A1
(43) Pub. Date: Apr. 15, 2010

(54) METHOD FOR MANUFACTURING IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/575,697

(22) Filed: Oct. 8, 2009

(30) Foreign Application Priority Data
Oct. 14, 2008 (KR) 10-2008-0100584

(51) Int. Cl. H01L 31/02; C23F 1/08

(52) U.S. Cl. 438/98; 156/345.11; 257/E31.11

(57) ABSTRACT

In a method for manufacturing an image sensor, readout circuitry is formed in a first substrate. A first interlayer dielectric is formed over the first substrate. An interconnection is formed at the first interlayer dielectric, and the interconnection is electrically connected to the readout circuitry. A second interlayer dielectric is formed over the interconnection. A via hole exposing an upper side of the interconnection is formed by etching a portion of the second interlayer dielectric using a photoresist pattern as an etch mask. A contact plug is formed in the via hole, while leaving the photoresist pattern. The photoresist pattern is then removed. An image sensing device is formed over the contact plug.

The present application claims priority under 35 U.S.C. 119 to Korean Patent Application No. 10-2008-0100584 (filed on Oct. 14, 2008), which is hereby incorporated by reference in its entirety.

### BACKGROUND

An image sensor is a semiconductor device for converting an optical image into an electric signal. Image sensors may be roughly classified into charge coupled device (CCD) image sensors and complementary metal oxide silicon (CMOS) image sensors (CIS).

During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

Also, since the stack height is not reduced in proportion to the reduction in the area of the light receiving portion, the number of photons incident to the light receiving portion is also reduced due to Airy disk diffraction of light.

As alternatives to overcome this limitation, attempts to form a photodiode using amorphous silicon (Si), to form readout circuitry in a silicon (Si) substrate using a method such as wafer-to-wafer bonding, or to form a photodiode on and/or over the readout circuitry have been made (referred to as a “three-dimensional (3D) image sensor”). The photodiode is connected with the readout circuitry through a metal interconnection.

According to the related art, when uniformity and adhesion between a logic substrate where readout circuitry is formed and an upper substrate where a photodiode is formed are excellent, satisfactory Si bonding can be achieved. For this, a contact plug is formed in a via hole area on a top layer before the logic substrate is bonded to the upper substrate. In this case, to form the contact plug in the via hole area, metal is filled in a via hole. Roughness or uniformity of the surface should be maintained constant through a CMP process or a wet process. However, it is actually impossible to control overall uniformity of a substrate to be a Root Mean Square (RMS) of about 3 nm or about 5 nm or less.

In addition, since both the source and the drain of the transfer transistor are heavily doped with N-type impurities in a related art, a charge sharing phenomenon occurs. When the charge sharing phenomenon occurs, the sensitivity of an output image is reduced and image errors may be generated. Also, because photo charge does not readily move between the photodiode and the readout circuitry, a dark current may be generated and/or saturation and sensitivity may be reduced.

### SUMMARY

Embodiments provide a method for manufacturing an image sensor, which can achieve a fine patterning while increasing a fill factor even though roughness or uniformity is not improved through a CMP or wet process. Embodiments also provide a method for manufacturing an image sensor, which can increase a fill factor and avoid a charge sharing phenomenon.

Embodiments also provide a method for manufacturing an image sensor, which can minimize a dark current source and inhibit saturation reduction and sensitivity degradation by forming a smooth transfer path of photo charges between a photodiode and a readout circuit, and a method for manufacturing the same.

In embodiments, a method for manufacturing an image sensor may include forming readout circuitry on a first substrate, forming a first interlayer dielectric over the first substrate, forming an interconnection at the first interlayer dielectric, the interconnection being electrically connected to the readout circuitry, forming a second interlayer dielectric over the interconnection, forming a via hole exposing an upper side of the interconnection by etching a portion of the second interlayer dielectric using a photoresist pattern as an etch mask, forming a contact plug in the via hole, removing the photoresist pattern, and forming an image sensing device over the contact plug.

Embodiments relate to an apparatus which may be configured to form readout circuitry on a first substrate, form a first interlayer dielectric over the first substrate, form an interconnection at the first interlayer dielectric, the interconnection being electrically connected to the readout circuitry, form a second interlayer dielectric over the interconnection, form a via hole exposing an upper side of the interconnection by etching a portion of the second interlayer dielectric using a photoresist pattern as an etch mask, form a contact plug in the via hole, remove the photoresist pattern, and form an image sensing device over the contact plug.

### DRAWINGS

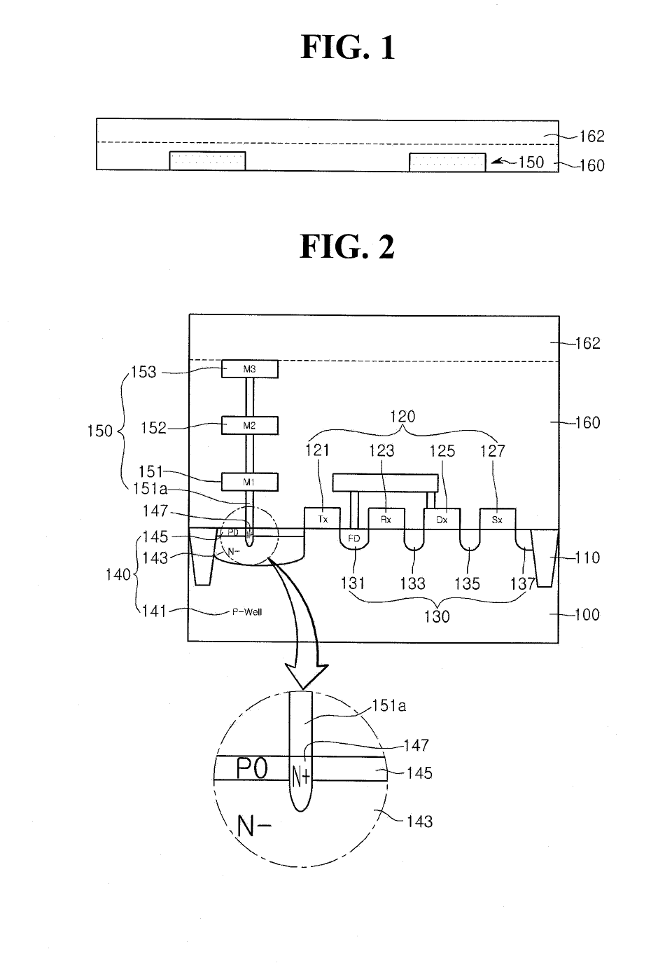

Example FIGS. 1 through 6 are cross-sectional views illustrating a method for manufacturing an image sensor according to embodiments.

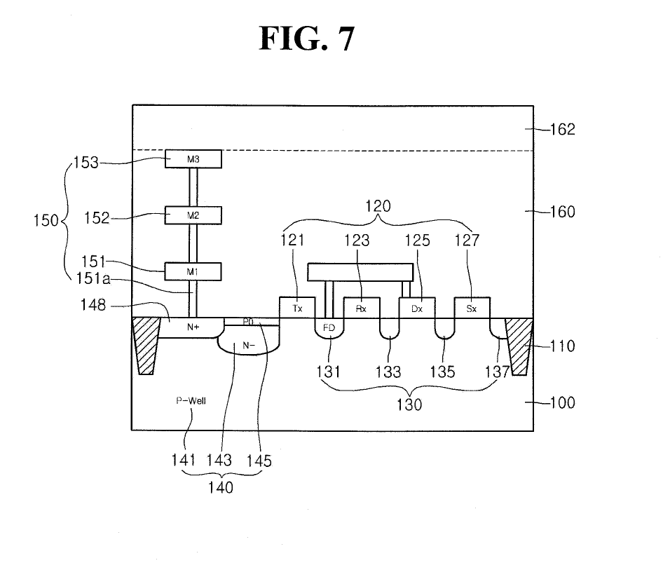

Example FIG. 7 is a cross-sectional view of an image sensor according to embodiments.

### DESCRIPTION

Hereinafter, a method for manufacturing an image sensor according to embodiments will be described in detail with reference to example FIGS. 1 through 6. Example FIG. 1 is a schematic view of a first substrate 100 where an interconnection 150 is formed, and example FIG. 2 is a detailed view illustrating the first substrate 100 where the interconnection 150 is formed.

As shown in example FIG. 2, first substrate 100 may include interconnection 150 and readout circuitry 120. For example, an active region may be defined by forming a device isolation layer 110 in the first substrate 100 of a second conductivity type. The readout circuitry 120 including transistors may be formed in the active region. For instance, the readout circuitry 120 may include a transfer transistor (Tx) 121, a reset transistor (Rx) 123, a drive transistor (Dx) 125, and a select transistor (Sx) 127. An ion implantation region 130, including a floating diffusion region (FD) 131 and source/drain regions 133, 135 and 137 for each transistor, may be formed.

The method for manufacturing an image sensor may include forming the electrical junction region 140 in the first substrate 100, and forming a first conductivity type connection 147 connected to the interconnection 150 at an upper part of the electrical junction region 140. For example, the electrical junction region 140 may be a P−N junction 140, but is not limited thereto. For example, the electrical junction region 140 may include a first conductivity type ion implantation region 143 formed on a second conductivity type well 141 or a second conductivity type epitaxial layer, and a second conductivity type ion implantation layer 145 formed on the first conductivity type ion implantation 143. For example, as shown in example FIG. 2, the P−N junction 140 may be a P0(145)/N−(143)/P−(141) junction, but is not limited thereto. The first substrate 100 may be a second conductivity type, but is not limited thereto.

According to embodiments, the device is designed to provide a potential difference between the source and drain of the transfer transistor (Tx), thus implementing the full dumping of a photo charge. Accordingly, a photo charge generated in the photodiode is dumped to the floating diffusion region, thereby increasing the output image sensitivity.

That is, as described in example FIG. 2, embodiments form the electrical junction region 140 in the first substrate 100 including the readout circuit 120 to provide a potential difference between the source and drain of the transfer transistor (Tx) 121, thereby implementing the full dumping of a photo charge. Thus, unlike the related art case of connecting a photodiode simply to an N+ junction, embodiments make it possible to prevent saturation reduction and sensitivity degradation.

Thereafter, a first conductivity type connection 147 may be formed between the photodiode and the readout circuit to create a smooth transfer path of a photo charge, thereby making it possible to minimize a dark current source and prevent saturation reduction and sensitivity degradation.

To this end, embodiments may form an n+ doping region as a first conductivity type connection 147 for an ohmic contact on the surface of the P0/N−/P− junction 140. The N+ region (147) may be formed such that it pierces the P0 (145) to contact the N− (143).

On the other hand, the width of the first conductivity type connection 147 may be minimized to prevent the first conductivity type connection 147 from being a leakage source. To this end, embodiments may include performing a plug implant process after etching a first metal contact 151a, but is not limited thereto. For example, an ion implantation pattern may be formed by another method, and it may be used as an ion implantation mask to form the first conductivity type connection 147. That is, the reason why an N+ doping is performed only on a contact formation region is to minimize a dark signal and help the smooth formation of an ohmic contact. If the entire Tx source region is N+ doped like the related art, a dark signal may increase due to an Si surface dangling bond.

Next, an interlayer dielectric 160 may be formed over the first substrate 100, and an interconnection 150 may be formed. The interconnection 150 may include a first metal contact 151a, a first metal 151, a second metal 152, and a third metal 153, but embodiments are not limited thereto. Thereafter, a second interlayer dielectric 162 may be formed over the interconnection 150.

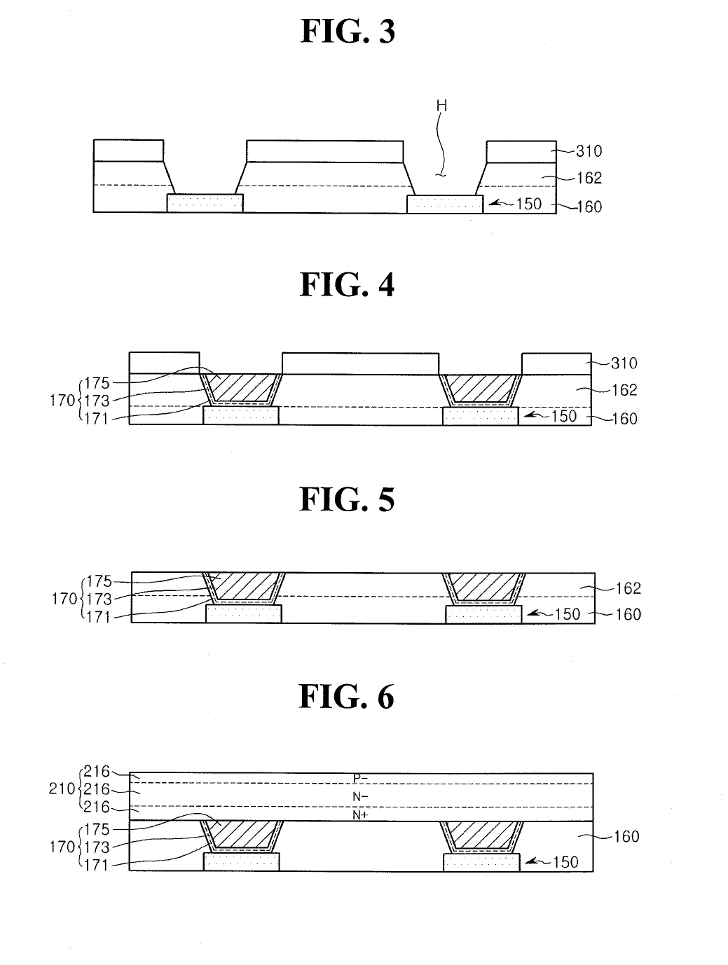

Next, as shown in example FIG. 3, a photoresist pattern 310 may be formed over the second interlayer dielectric 162. A via hole H may be formed to expose an upper side of the interconnection 150 by etching a portion of the second interlayer dielectric 162 using the photoresist pattern 310 as an etch mask. For example, a surface of a third metal 153 may be exposed by etching the second interlayer dielectric 162 over a third metal 153 using the photoresist pattern 310 as an etch mask.

Next, as shown in example FIG. 4, a contact plug 170 may be formed in the via hole H to leave the photoresist pattern. For example, the contact plug 170 may be formed by depositing Ti(171)/TiN(173/Al(175) while leaving the photoresist pattern 310.

The method for manufacturing an image sensor proposes a method capable of performing a fine patterning by forming a metal for contact plug in only a via hole, not the entire substrate without removing a photoresist pattern even though roughness or uniformity is not improved through a CMP or wet process, improving properties of a 3D image sensor.

Next, as shown in example FIG. 5, the photoresist pattern 310 is removed. For example, the photoresist pattern may be removed through a process for about 5 minutes to about 30 minutes using a mixture solution of H₂SO₄: H₂O₂=2˜10:1. In other words, the mixture solution contains approximately two to ten parts H₂SO₄ to one part H₂O₂.

After the photoresist pattern 310 is removed, a cleaning process is performed using a mixture solution of TMH (Trimethylammoniumhydroxide): H₂O₂: H₂O=1:2˜10:30˜50. Thus, roughness of first substrate 100 is reduced and particles are removed, thereby improving bonding strength of an upper substrate to an image sensing device.

Next, as shown in example FIG. 6, an image sensing device 210 may be formed over the contact plug 170. For example, a photodiode including a high-concentration first conductivity type layer 212, a first conductivity type layer 214, and a second conductivity type layer 216 may be formed over a crystalline semiconductor layer of a second substrate. For example, a photodiode including an N+ layer 212, an N− layer 214, and a P− layer 216 may be formed.

Next, the first substrate 100 and the second substrate are bonded to each other so that the image sensing device 210 may correspond to the contact plug 170, and the second substrate is removed to leave the image sensing device 210. In this case, an insulating layer or a metal layer may be interposed between the first substrate 100 and the second substrate.

Thereafter, an etching process for dividing the image sensing device 210 into pixels may be performed to fill interpixel insulating layers in etched portions of pixels, separating the image sensing device 210 into pixels. Next, processes to form an upper electrode and a color filter may be performed.

Example FIG. 7 is a cross-sectional view of an image sensor according to embodiments, and is a detailed view of a first substrate where an interconnection 150 is formed. Where not otherwise specified, embodiments illustrated in example FIG. 7 may adopt the technical features of embodiments shown in example FIGS. 1-6.

Embodiments shown in example FIG. 7 include an example wherein a first conductivity type connection 148 is formed at one side of an electrical junction region 140. An N+ connection region 148 may be formed at a P0/N−/P− junction 140 for an ohmic contact. In a process of forming an N+ connection region 148 and a M1C contact 151a, a leakage source may occur. This is because an electric field (EF) may be generated over the Si surface due to operation while a reverse bias is applied to P0/N−/P− junction 140. A crystal defect generated during the contact forming process inside the electric field may become a leakage source.

Also, when the N+connection region 148 is formed over the surface of P0/N−/P− junction 140, an electric field may be additionally generated due to N+/P0 junction 148/145. This electric field may also become a leakage source.

Therefore, embodiments propose a layout in which first contact plug 151a is formed in an active region not doped with a P0 layer but including N+ connection region 148 and is connected to N−junction 143. According to embodiments, the electric field is not generated on and/or over the Si surface, which can contribute to reduction in a dark current of a 3-D integrated CIS.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming readout circuitry on a first substrate;
forming a first interlayer dielectric over the first substrate;
forming an interconnection at the first interlayer dielectric, the interconnection being electrically connected to the readout circuitry;
forming a second interlayer dielectric over the interconnection;
forming a via hole exposing an upper side of the interconnection by etching a portion of the second interlayer dielectric using a photoresist pattern as an etch mask;
forming a contact plug in the via hole;
removing the photoresist pattern; and
forming an image sensing device over the contact plug.

2. The method of claim 1, wherein the removing of the photoresist pattern includes processing for about 5 minutes to about 30 minutes using a mixture solution of H₂SO₄ and H₂O₂.

3. The method of claim 2, wherein the mixture solution is mixed in a ratio of between 2 and 10 parts H₂SO₄ to one part H₂O₂.

4. The method of claim 1, including performing a cleaning process using a mixture solution of trimethylammoniumhydroxide, H₂O₂, and H₂O after the removing of the photoresist pattern.

5. The method of claim 4, wherein the mixture solution is mixed in a ratio of one part trimethylammoniumhydroxide to between two and ten parts H₂O₂ to between thirty and fifty parts H₂O.

6. The method of claim 1, including forming an electrical junction region at the first substrate, the electrical junction region being electrically connected to the readout circuitry.

7. The method of claim 6, wherein the forming of the electrical junction region includes:
forming a first conductivity type ion implantation region at the first substrate; and
forming a second conductivity type ion implantation region on the first conductivity type ion implantation region.

8. The method of claim 6, wherein the readout circuitry has a potential difference between a source and a drain of a transistor.

9. The method of claim 8, wherein the transistor is a transfer transistor.

10. The method of claim 9, wherein an ion implantation concentration of the transistor source is smaller than an ion implantation concentration of a floating diffusion region.

11. The method of claim 6, wherein the electrical junction region is a PN junction.

12. The method of claim 9, wherein the electrical junction region is a PNP junction.

13. The method of claim 6, including forming a first conductivity type connection between the electrical junction region and the interconnection.

14. The method of claim 13, wherein the first conductivity type connection is electrically connected to the interconnection at an upper part of the electrical junction region.

15. The method of claim 13, wherein the first conductivity type connection is electrically connected to the interconnection at one side of the electrical junction region.

16. An apparatus configured to:
form readout circuitry on a first substrate;
form a first interlayer dielectric over the first substrate;
form an interconnection at the first interlayer dielectric, the interconnection being electrically connected to the readout circuitry;
form a second interlayer dielectric over the interconnection;
form a via hole exposing an upper side of the interconnection by etching a portion of the second interlayer dielectric using a photoresist pattern as an etch mask;
form a contact plug in the via hole;
remove the photoresist pattern; and
form an image sensing device over the contact plug.

17. The apparatus of claim 1, configured to remove the photoresist pattern by processing for about 5 minutes to about 30 minutes using a mixture solution of H₂SO₄ and H₂O₂, wherein the mixture solution is mixed in a ratio of between 2 and 10 parts H₂SO₄ to one part H₂O₂.

18. The apparatus of claim 16, configured to perform a cleaning process using a mixture solution of trimethylammoniumhydroxide, H₂O₂, and H₂O after the removing of the photoresist pattern, wherein the mixture solution is mixed in a ratio of one part trimethylammoniumhydroxide to between two and ten parts H₂O₂ to between thirty and fifty parts H₂O.

19. The apparatus of claim 16, configured to form an electrical junction region at the first substrate, the electrical junction region being electrically connected to the readout circuitry.

20. The apparatus of claim 19, configured to form the electrical junction region by:
forming a first conductivity type ion implantation region at the first substrate; and
forming a second conductivity type ion implantation region on the first conductivity type ion implantation region.
